(19) United States
(12) Patent Application Publication
(10) Pub. No.: US 2026/0018743 A1
(43) Pub. Date: Jan. 15, 2026

(54) VOLTAGE MONITORING MODULE, BATTERY MODULE, AND SUPPORT CASE

(71) Applicant: MEKTEC CORPORATION, Tokyo (JP)

(72) Inventors: Takuya HOSOKAWA, Tokyo (JP); Kenji KIYA, Tokyo (JP); Tomoki KANAYAMA, Tokyo (JP)

(73) Assignee: MEKTEC CORPORATION, Tokyo (JP)

(21) Appl. No.: 19/188,954

(22) Filed: Apr. 24, 2025

(30) Foreign Application Priority Data
Jul. 12, 2024 (JP) 2024-112417

(51) Int. Cl. H01M 50/503; G01R 31/36; G01R 31/3835; H01M 10/48; H01M 50/209; H01M 50/284; H01M 50/519

(52) U.S. Cl. CPC H01M 50/503; G01R 31/3644; G01R 31/3835; H01M 10/482; H01M 50/209; H01M 50/284; H01M 50/519

(57) ABSTRACT

A voltage monitoring module includes a flexible printed circuit board and a support case supporting the flexible printed circuit board. The flexible printed circuit board includes a body and a branch branched from the body and having an extension extending in a first direction which is the longitudinal direction of the body. The branch has, at a tip end portion thereof, a connection terminal to be connected to a cell terminal of a battery cell. The support case includes a first case, a second case on which the body is to be mounted and which is provided movably in the first direction relative to the first case, and a movement restrictor that restricts movement of the second case after the second case has moved to a final set position.

### CROSS-REFERENCE TO RELATED APPLICATION

This application is based on Japanese Patent Application No. 2024-112417 filed with the Japan Patent Office on Jul. 12, 2024, the entire content of which is hereby incorporated by reference.

### BACKGROUND

### 1. Technical Field

One aspect of the present disclosure relates to a voltage monitoring module, a battery module, and a support case.

### 2. Related Art

JP-A-2020-013766 describes a voltage monitoring module (busbar module in this literature). This voltage monitoring module monitors the state of the voltage of a cell laminate (battery assembly in this literature) including a plurality of battery cells (unit batteries in this literature) laminated on each other. This voltage monitoring module includes a flexible printed circuit board (flexible board in this literature) having a plurality of lines. The flexible printed circuit board has a body (main line in this literature) and a branch (branch line in this literature) branched form the body and having an extension extending in a first direction which is the longitudinal direction of the body. The branch has, at a tip end portion thereof, a connection terminal to be connected to a cell terminal which is a terminal of the battery cell. In the technique of JP-A-2020-013766, the branch of the flexible printed circuit board is a folded portion in a folded-back shape. Thus, the connection terminal can follow movement of the cell terminal along with contraction or expansion of the battery cell.

### SUMMARY

A voltage monitoring module for monitoring a state of a voltage of a cell laminate including a plurality of battery cells laminated on each other, the voltage monitoring module including: a flexible printed circuit board having a plurality of lines; and a support case supporting the flexible printed circuit board, in which the flexible printed circuit board includes a body and a branch branched from the body and having an extension extending in a first direction which is a longitudinal direction of the body, the branch has, at a tip end portion thereof, a connection terminal to be connected to a cell terminal which is a terminal of each battery cell, the support case includes a first case, a second case having a body mounting portion on which the body is to be mounted and provided movably in the first direction relative to the first case, and a movement restrictor that restricts movement of the second case, which is disposed at a final set position which is a position of the second case after the second case has moved in the first direction relative to the first case, relative to the first case.

### BRIEF DESCRIPTION OF DRAWINGS

FIG. 1 is a perspective view of a battery module according to an embodiment in a state of a second case of a support case being disposed at an initial set position;

FIG. 2 is a plan view of a flexible printed circuit board forming a voltage monitoring module according to the embodiment;

FIG. 3 is a perspective view of the support case forming the voltage monitoring module according to the embodiment;

FIG. 4 is a perspective view of the voltage monitoring module according to the embodiment;

FIG. 5 is a perspective view of the battery module according to the embodiment in a state of the second case of the support case being disposed at a final set position;

FIG. 6 is a partially-enlarged view of FIG. 5;

FIG. 7 is a plan view of the battery module according to the embodiment;

FIG. 8A is a perspective view of a first case of the support case, FIG. 8B is a plan view of the first case, FIG. 8C is a side view of the first case, and FIG. 8D is a side sectional view (sectional view taken along A-A line in FIG. 8B) of the first case;

FIG. 9A is a perspective view of the second case of the support case, and FIG. 9B is a perspective view of the second case from the back side;

FIG. 10A is a plan view of the second case, FIG. 10B is a side view (view in the direction of an arrow B in FIG. 10A) of the second case, FIG. 10C is a bottom view of the second case, FIG. 10D is a side view (view in the direction of an arrow D in FIG. 10A) of the second case from the opposite side, and FIG. 10E is a side sectional view (sectional view taken along A-A line in FIG. 10A) of the second case;

FIG. 11 is a perspective view showing an initial stage (stage before the second case is disposed at the initial set position) of assembling the first and second cases of the support case;

FIG. 12 is a perspective view showing a state of the first and second cases of the support case being assembled and the second case being moved to the initial set position;

FIG. 13 is a perspective view showing a state of the first and second cases of the support case being assembled and the second case being moved to the final set position;

FIGS. 14A, 14B, and 14C are enlarged side sectional views (sectional views at a position corresponding to C-C line in FIG. 3) of a main portion, which show a movement restrictor of the support case, FIG. 14A corresponding to the state of FIG. 11, FIG. 14B corresponding to the state of FIG. 12, and FIG. 14C corresponding to the state of FIG. 13; and

FIG. 15A is an enlarged front sectional view (sectional view taken along B-B line in FIG. 3) of a main portion, which shows a linear guide structure of the support case, and FIG. 15B is an enlarged perspective sectional view (perspective sectional view at a position along A-A line in FIG. 3) of a main portion, which shows the linear guide structure.

### DETAILED DESCRIPTION

In the following detailed description, for purpose of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

However, in the technique of JP-A-2020-013766, the connection terminal at the tip end of the branch is connected to the cell terminal in a state of the branch of the flexible printed circuit board being formed with the folded portion. Thus, a process of assembling the flexible printed circuit board is complicated.

One object of the present disclosure is to provide a voltage monitoring module, a battery module, and a support case which enable a connection terminal to easily follow movement of a cell terminal along with contraction or expansion of a battery cell.

A voltage monitoring module according to one aspect of the present disclosure (this voltage monitoring module) is for monitoring a state of a voltage of a cell laminate including a plurality of battery cells laminated on each other. The voltage monitoring module includes: a flexible printed circuit board having a plurality of lines; and a support case supporting the flexible printed circuit board. The flexible printed circuit board includes a body and a branch branched from the body and having an extension extending in a first direction which is a longitudinal direction of the body, the branch has, at a tip end portion thereof, a connection terminal to be connected to a cell terminal which is a terminal of each battery cell, the support case includes a first case, a second case having a body mounting portion on which the body is to be mounted and provided movably in the first direction relative to the first case, and a movement restrictor that restricts movement of the second case, which is disposed at a final set position which is a position of the second case after the second case has moved in the first direction relative to the first case, relative to the first case.

Further, a battery module according to one aspect of the present disclosure includes: the voltage monitoring module; and the cell laminate. After the second case has been disposed at an initial set position which is a position of the second case before the second case moves in the first direction relative to the first case, the body has been mounted on the body mounting portion, and the connection terminal of the flexible printed circuit board has been connected to the cell terminal of the cell laminate, the second case moves to the final set position in the first direction relative to the first case, and the extension bends in a direction perpendicular to a plane of the extension.

Further, a support case according to one aspect of the present disclosure includes: a first case; a second case having a body mounting portion on which a body of a flexible printed circuit board is to be mounted and movably provided in a first direction, which is a longitudinal direction of the body, relative to the first case; and a movement restrictor that restricts movement of the second case, which is disposed at a final set position which is a position of the second case after the second case has moved in the first direction relative to the first case, relative to the first case.

According to one aspect of the present disclosure, the connection terminal can easily follow movement of the cell terminal along with contraction or expansion of the battery cell.

Hereinafter, an embodiment of the present disclosure will be described with reference to the drawings. Note that in all the drawings, the same reference numerals are used to represent similar components and description thereof will be omitted as necessary.

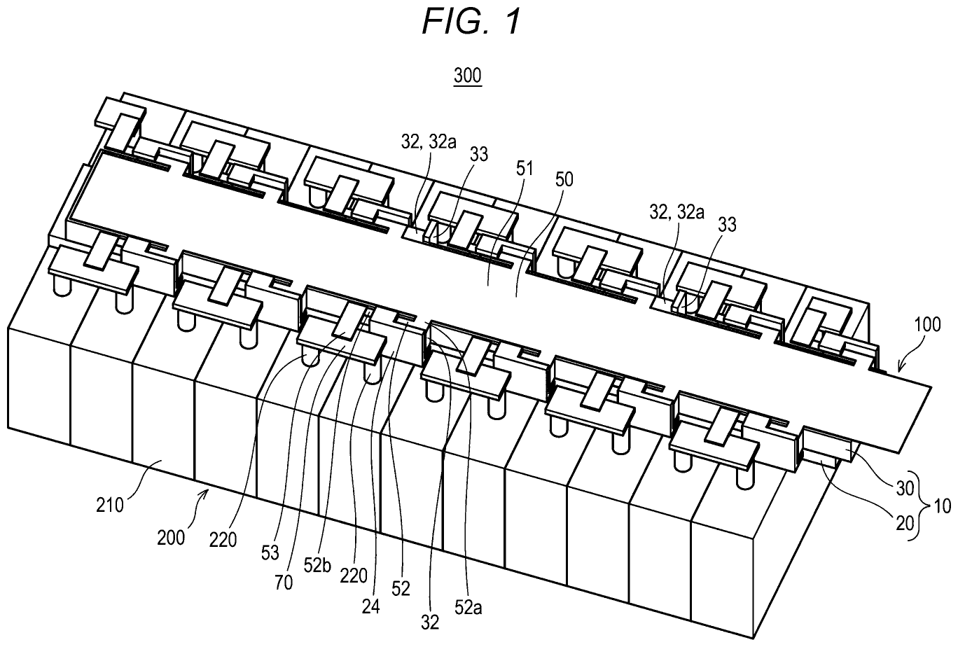

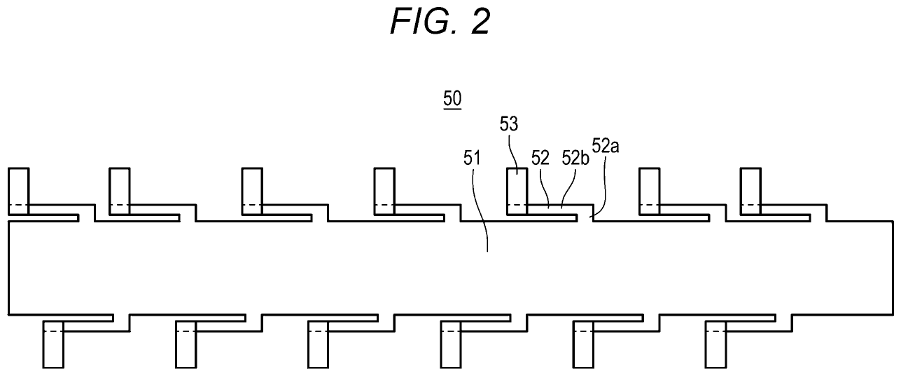

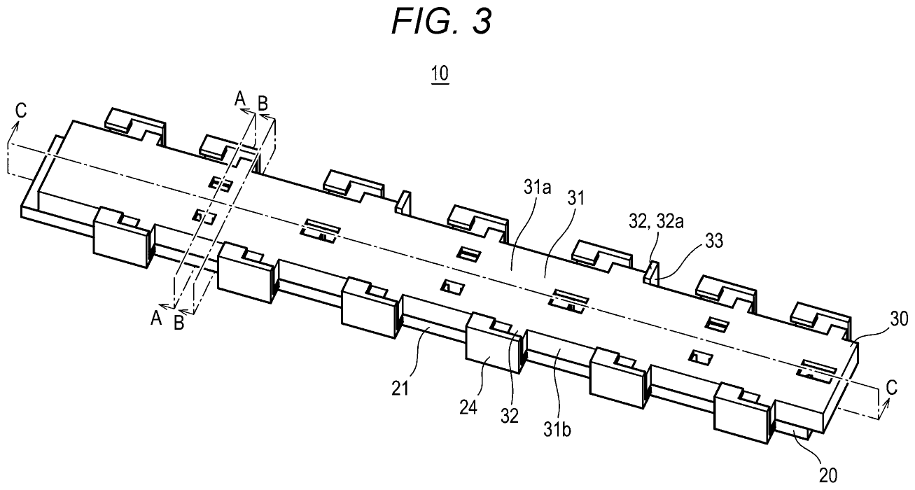

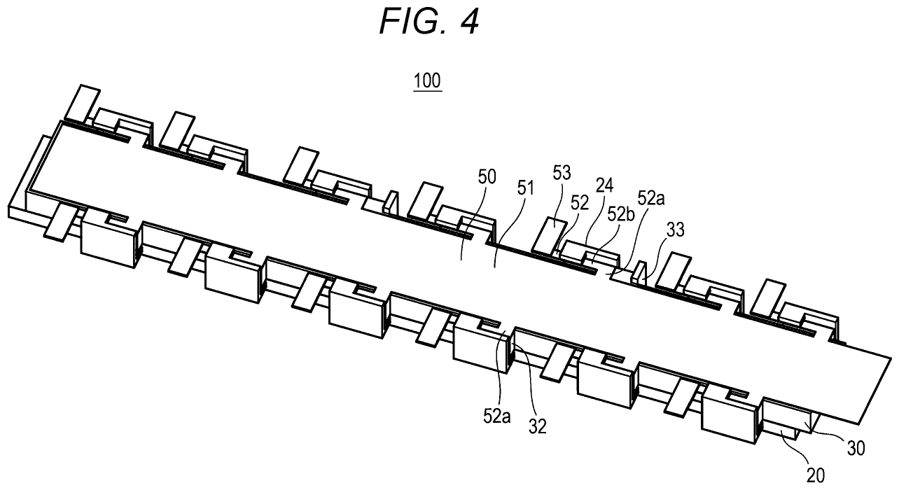

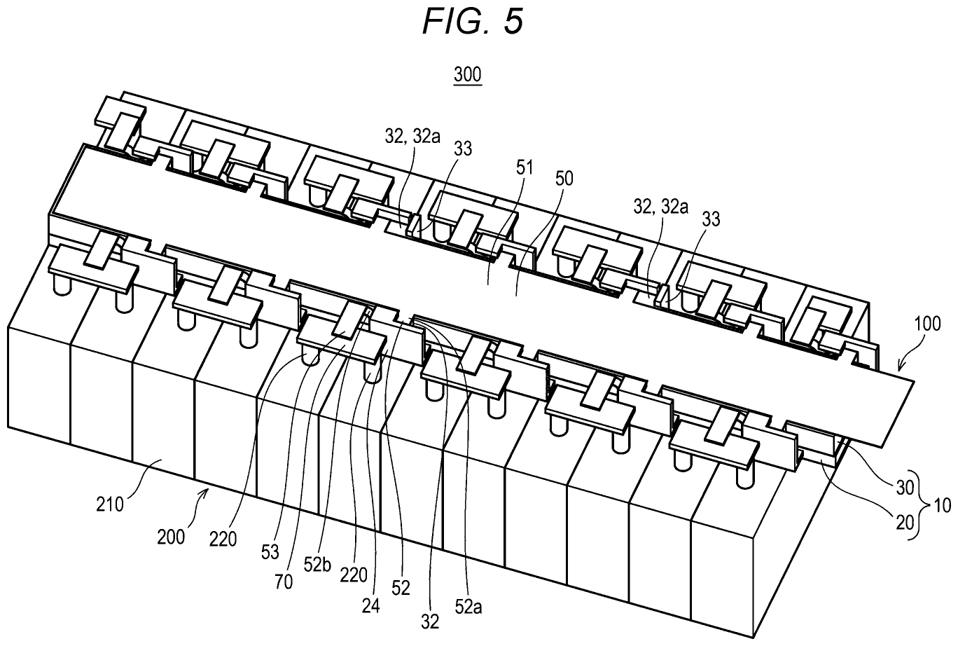

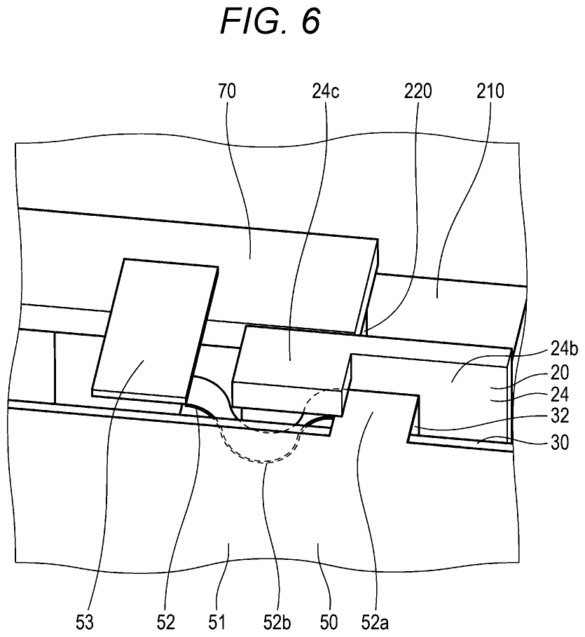

As shown in FIG. 1, a voltage monitoring module 100 according to the present embodiment is used for monitoring the state of the voltage of a cell laminate 200 including a plurality of battery cells 210 laminated on each other. The voltage monitoring module 100 includes a flexible printed circuit board 50 having a plurality of lines (not shown), and a support case 10 supporting the flexible printed circuit board 50. As shown in FIG. 2, the flexible printed circuit board 50 includes a body 51 and a branch 52 branched from the body 51 and having an extension 52b extending in a first direction (right-left direction in FIG. 2) which is the longitudinal direction of the body 51. The branch 52 has, at a tip end portion thereof, a connection terminal 53 to be connected to a cell terminal 220 (FIG. 1) which is a terminal of the battery cell 210. As shown in FIGS. 3 and 4, the support case 10 includes a first case 20 and a second case 30 having a body mounting portion (plate-shaped portion 31a to be described later) on which the body 51 is to be mounted and provided movably in the first direction relative to the first case 20. The support case 10 includes a movement restrictor (including an engagement portion 22 and an engagement portion 34 to be described later) that restricts movement of the second case 30, which is disposed at a final set position (position in FIGS. 5 and 6) which is the position of the second case 30 after the second case 30 has moved in the first direction relative to the first case 20, relative to the first case 20.

According to the present embodiment, when the second case 30 is disposed at an initial set position (position in FIG. 1), the body 51 is mounted on the body mounting portion of the second case 30, and each connection terminal 53 of the flexible printed circuit board 50 is connected to a corresponding one of the cell terminals 220 of the cell laminate 200. The initial set position is the position of the second case 30 before the second case 30 moves in the first direction relative to the first case 20. Thereafter, the second case 30 moves to the final set position in the first direction relative to the first case 20. Accordingly, the extension 52b bends in a direction perpendicular to the plane of the extension 52b (see FIG. 6). Thus, the extension 52b is easily stretchable and contractable in the first direction. Consequently, the connection terminal 53 can favorably follow movement of the cell terminal 220 corresponding to each connection terminal 53 along with contraction or expansion of the battery cell 210. That is, the amount of bending of the extension 52b increases or decreases so that each connection terminal 53 can favorably follow movement of a corresponding one of the cell terminals 220. Moreover, in a state of each extension 52b extending flat (see FIG. 4), the flexible printed circuit board 50 can be mounted on the body mounting portion of the second case 30. Thus, attachment of the flexible printed circuit board 50 to the second case 30 is facilitated. After each connection terminal 53 has been connected to a corresponding one of the cell terminals 220, the second case 30 is moved to the final set position in the first direction relative to the first case 20, and accordingly, the extension 52b bends in the direction perpendicular to the plane of the extension 52b. The support case 10 includes the movement restrictor that restricts movement of the second case 30, which is disposed at the final set position which is the position of the second case 30 after the second case 30 has moved in the first direction relative to the first case 20, relative to the first case 20. Thus, the support case 10 can maintain the bent state of each extension 52b (FIGS. 5 and 6). As described above, according to the present embodiment, the connection terminal 53 can easily follow movement of the cell terminal 220 along with contraction or expansion of the battery cell 210.

A battery module 300 according to the present embodiment includes the voltage monitoring module 100 according to the present embodiment and the cell laminate 200. For example, when the second case 30 is disposed at the initial set position which is the position of the second case 30 before the second case 30 moves in the first direction relative to the first case 20, the body 51 is mounted on the body mounting portion, and each connection terminal 53 of the flexible printed circuit board 50 is connected to a corresponding one of the cell terminals 220 of the cell laminate 200. Thereafter, the second case 30 moves to the final set position in the first direction relative to the first case 20. Accordingly, the extension 52b bends in the direction perpendicular to the plane of the extension 52b.

The support case 10 according to the present embodiment is the support case 10 of the voltage monitoring module 100 according to the present embodiment. That is, the support case 10 includes the first case 20, the second case 30 having the body mounting portion on which the body 51 of the flexible printed circuit board 50 is to be mounted and provided movably in the first direction, which is the longitudinal direction of the body 51, relative to the first case 20, and the movement restrictor that restricts movement of the second case 30, which is disposed at the final set position which is the position of the second case 30 after the second case 30 has moved in the first direction relative to the first case 20, relative to the first case 20.

Hereinafter, the embodiment of the present disclosure will be described in more detail.

The voltage monitoring module 100 is disposed along the cell laminate 200 such that the longitudinal direction (i.e., the first direction) of the body 51 of the flexible printed circuit board 50 is along the lamination direction of the battery cells 210. Each connection terminal 53 is connected to a corresponding one of the cell terminals 220. Upon discharging of the cell laminate 200, the plurality of battery cells 210 contracts in the lamination direction. Along with contraction of the plurality of battery cells 210, the arrangement interval of the cell terminals 220 in the first direction is narrowed. Accordingly, the arrangement interval of the connection terminals 53 in the first direction is also narrowed. On the other hand, upon charging of the cell laminate 200, the plurality of battery cells 210 expands in the lamination direction. Along with expansion of the plurality of battery cells 210, the arrangement interval of the cell terminals 220 in the first direction is expanded, and accordingly, the arrangement interval of the connection terminals 53 in the first direction is also expanded.

As shown in FIG. 1, the battery module 300 includes, for example, a plurality of busbars 70. These busbars 70 connect the plurality of battery cells 210 in series. Note that the present embodiment is not limited to this example and the busbars 70 may connect some of the plurality of battery cells 210 in parallel. Each busbar 70 is disposed over adjacent ones of the cell terminals 220 of the battery cells 210, and is connected (for example, by laser-welded) to these cell terminals 220. The shape of the busbar 70 is not particularly limited. As the busbar 70, for example, a flat plate-shaped metal member may be used.

For example, a connector is attached to the flexible printed circuit board 50. The flexible printed circuit board 50 is connected through the connector to a measurement device that performs various types of control. Thus, the voltage can be monitored. For example, the wiring of the flexible printed circuit board 50 is connected to the busbars 70 connecting the plurality of battery cells 210, so that the flexible printed circuit board 50 can be used for monitoring the voltage. The planar shape of the body 51 of the flexible printed circuit board 50 is not particularly limited. In the present embodiment, for example, as shown in FIG. 2, the planar shape of the body 51 is a substantially rectangular shape long in the first direction. The branch 52 has, for example, a protrusion 52a and the extension 52b. The protrusion 52a protrudes laterally (upward or downward in FIG. 2) from an end portion of the body 51 in the width direction thereof. The extension 52b extends in the first direction from a tip end portion of the protrusion 52a in the protruding direction thereof. The tip end portion of the extension 52b is provided with the connection terminal 53. The extension 52b linearly extends in plan view, for example. The flexible printed circuit board 50 is formed such that the entirety thereof including the body 51 and the branch 52 is flat in a normal state. Note that the extension 52b of each branch 52 bends in the direction perpendicular to the plane of the extension 52b when the second case 30 moves in the first direction relative to the first case 20 in a state of the flexible printed circuit board 50 being mounted on the second case 30 of the support case 10 and each connection terminal 53 being connected to a corresponding one of the cell terminals 220.

As shown in FIG. 2, the plurality of branches 52 includes a plurality of branches 52 having protrusions 52a protruding to one side (lower side in FIG. 2) from one side edge of the body 51 and a plurality of branches 52 having protrusions 52a protruding to the other side (upper side in FIG. 2) from the other side edge of the body 51. A direction of the extension 52b extending from the protrusion 52a is the same direction as a direction of the second case 30 moving from the initial set position to the final set position relative to the first case 20. Note that in the present embodiment, the plurality of branches 52 is not necessarily formed at each side edge of the body 51. For example, the branches 52 may be formed only at one side edge of the body 51. Each line extends from the inside of the body 51 to the tip end portion of the branch 52. For example, one line is disposed for each branch 52. One connection terminal 53 is formed at the tip end portion of the extension 52b of each branch 52. The tip end of each line is connected to a corresponding one of the connection terminals 53.

As shown in FIG. 3, the support case 10 includes the first case 20 and the second case 30 assembled with the first case 20. Each of the first case 20 and the second case 30 is integrally molded using a hard resin material, for example. The second case 30 is disposed on the first case 20, and is movable in the first direction relative to the first case 20. As shown in FIG. 4, the body 51 of the flexible printed circuit board 50 is fixed onto the second case 30. The first case 20 of the support case 10 in a state of the flexible printed circuit board 50 being fixed to the second case 30 is fixed (for example, bridged) to a housing 310 of the battery module 300 (described later). Meanwhile, the second case 30 is held by the first case 20 so as to move in the first direction, and is not directly fixed to the housing 310. Thus, even in a state of the first case 20 being fixed to the housing 310, the second case 30 is movable in the first direction relative to the first case 20.

As shown in FIG. 1, the connection terminal 53 at the tip end portion of each branch 52 of the flexible printed circuit board 50 fixed to the support case 10 is fixed to the busbar 70. Accordingly, each connection terminal 53 is electrically connected to the cell terminals 220 of the battery cell 210 through the busbar 70. By moving the second case 30 in the first direction (direction diagonally to the upper left in FIG. 1) relative to the first case 20, the extension 52b of each branch 52 bends in the direction (downward, for example) perpendicular to the plane of the extension 52b as shown in FIGS. 5 and 6. That is, the extension 52b bends in an arc shape projecting downward (U-shape).

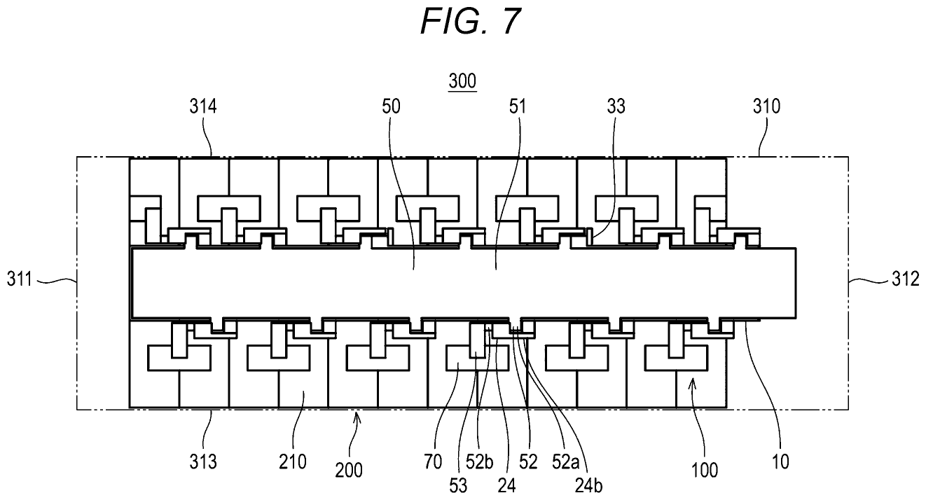

As shown in FIG. 7, the battery module 300 includes, for example, the housing 310 housing the cell laminate 200. Note that in FIG. 7, the housing 310 is indicated by a dash-dot-dot line. The housing 310 is formed, for example, in a rectangular parallelepiped box shape, and includes four walls surrounding the four sides thereof, i.e., a first wall 311, a second wall 312, a third wall 313, and a fourth wall 314. The first wall 311 and the second wall 312 face each other in parallel. The third wall 313 and the fourth wall 314 face each other in parallel. The third wall 313 and the fourth wall 314 are perpendicular to the first wall 311 and the second wall 312. Note that the battery module 300 may include a thermistor (not shown) that detects the temperature of the cell laminate 200 and wiring (not shown) connecting the thermistor to the measurement device that performs various types of control. The first case 20 of the support case 10 is fixed to the housing 310. A method of fixing the first case 20 to the housing 310 is not particularly limited. For example, the first case 20 may be fixed to the housing 310 through a fixing member (not shown). Alternatively, the first case 20 may be directly fixed to the housing 310. In the latter case, the first case 20 may be increased in size (extended in the right-left direction in FIG. 7) according to the size of the housing 310. The first case 20 may be fixed to the housing 310 using a fixing portion (for example, a hook portion to be fitted in the housing 310) formed for the first case 20. For example, the support case 10 is bridged between the first wall 311 and the second wall 312, and is disposed horizontally (the plate surfaces of the plate-shaped portion 31a and a body 21 to be described later are in a horizontal posture) above the cell laminate 200.

Each battery cell 210 is a secondary battery. As shown in FIGS. 1 and 5, each battery cell 210 is in the form of a flat plate having a rectangular shape in side view. The plurality of battery cells 210 is designed to have the same shape and the same dimensions. Each battery cell 210 has, for example, a pair of right and left cell terminals 220. The pair of right and left cell terminals 220 stands upward from the upper end surface of the battery cell 210, for example. The shape of the cell terminal 220 is not particularly limited, but in the present embodiment, is a circular columnar shape whose axial direction extends in an up-down direction, as one example. Note that the present embodiment is not limited to this example and the cell terminal 220 may be formed, for example, in a flat plate shape. The cell terminals 220 of adjacent ones of the battery cells 210 in the lamination direction are connected to each other through the busbar 70. The connection terminal 53 is connected to each busbar 70.

Hereinafter, the structure of the support case 10 will be described in more detail.

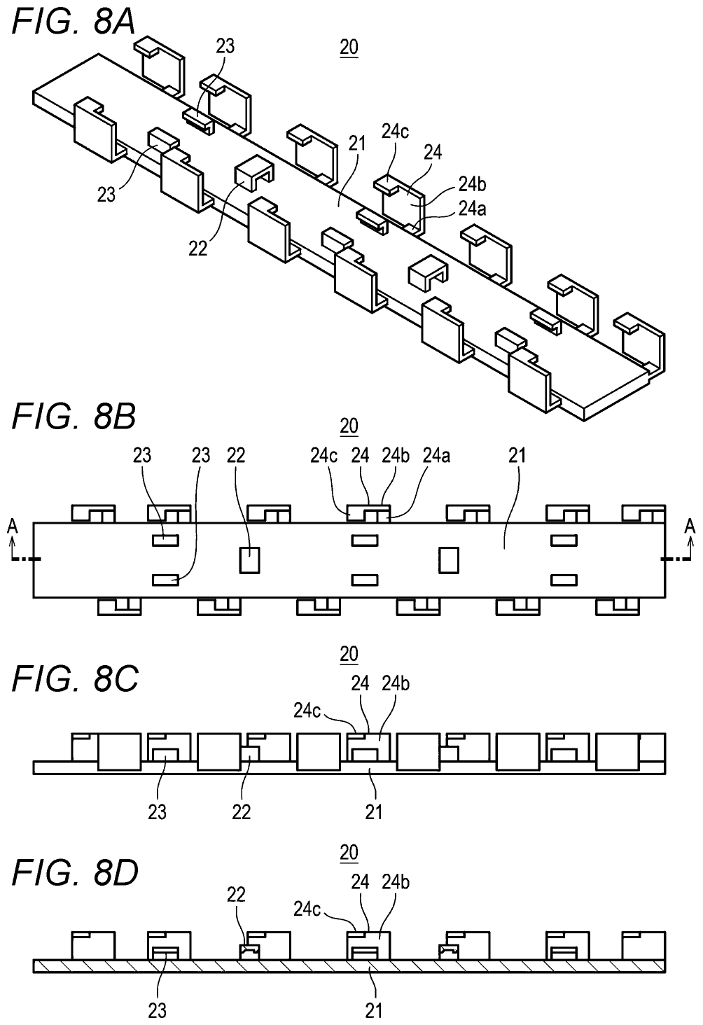

First, the first case 20 will be described with reference to FIGS. 8A to 8D. The first case 20 includes, for example, the flat plate-shaped body 21 long in the first direction, the engagement portion 22 and a guide portion 23 formed on the upper surface of the body 21, and a bending direction restrictor 24 formed at a side edge of the body 21. Note that the present embodiment is not limited to this example, and the engagement portion 22 and the guide portion 23 are not necessarily formed for the first case 20, but may be formed for the second case 30. In this case, the engagement portion 34 and a guide portion 35 to be described later are not formed for the second case 30, but for the first case 20. The body 21 is disposed horizontally.

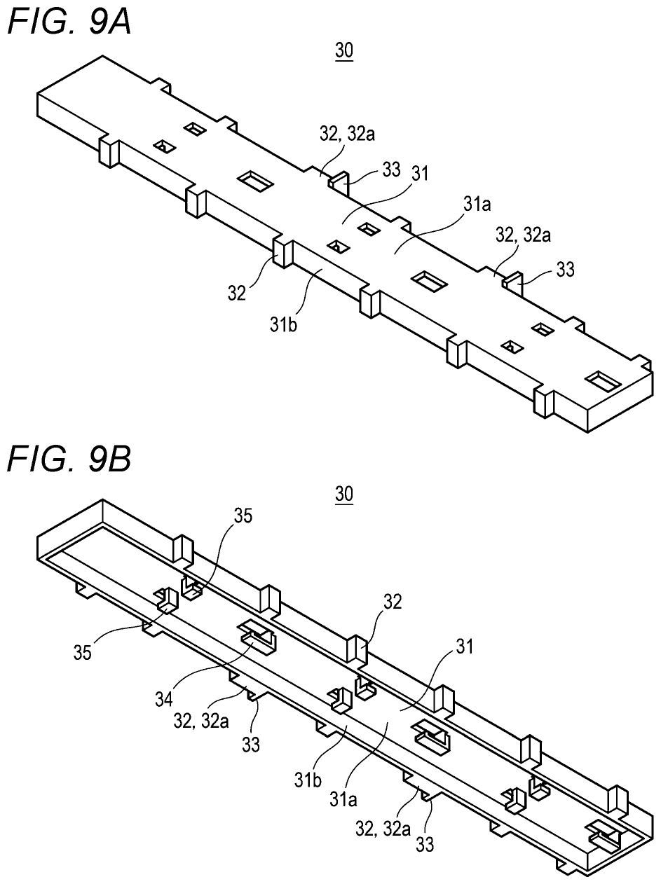

The engagement portion 22 is a portion disposed so as to protrude upward from the body 21 at a center portion of the body 21 in the width direction thereof and having a gate-shaped (inverted U-shaped) cross section as viewed from the front. The engagement portion 22 and the engagement portion 34 (see FIG. 9B and the like) of the second case 30 together form the movement restrictor. The number of engagement portions 22 provided for the first case 20 is not particularly limited. In the present embodiment, the first case 20 includes, for example, two engagement portions 22 disposed apart from each other in the first direction.

The guide portion 23 is disposed so as to protrude upward from the body 21 at a center portion of the body 21 in the width direction thereof. The guide portion 23 is a portion having an inverted L-shaped cross section as viewed from the front. The guide portion 23 includes a pair of right and left guide portions 23 disposed on the body 21. The pair of guide portions 23 is formed bilaterally symmetrically. The guide portion 23 and the guide portion 35 (FIG. 9B and the like) of the second case 30 together form a linear guide structure. The number of guide portions 23 provided for the first case 20 is not particularly limited. In the present embodiment, the first case 20 includes, for example, three pairs of guide portions 23 disposed apart from each other in the first direction. Note that the guide portion 23 and the engagement portion 22 are disposed at different positions in the first direction.

The bending direction restrictor 24 restricts the bending direction of the extension 52b to one direction in a direction perpendicular to the plane of the body 51 in a course of the second case 30 moving to the final set position in the first direction relative to the first case 20. Thus, the bending direction restrictor 24 is disposed corresponding to each branch 52 of the flexible printed circuit board 50. That is, the bending direction restrictor 24 includes a plurality of bending direction restrictors 24 formed at one side edge of the body 21 and a plurality of bending direction restrictors 24 formed at the other side edge of the body 21.

The bending direction restrictor 24 has an outwardly-standing wall 24b and a protruding piece 24c. The outwardly-standing wall 24b stands in the direction perpendicular to the plane of the body 51 on the outside of the outer line of the flexible printed circuit board 50 as viewed in the direction perpendicular to the plane of the body 51. The protruding piece 24c protrudes inward of the outer line from the outwardly-standing wall 24b, and covers the extension 52b. The bending direction restrictor 24 having such a configuration can restrict the bending direction of the extension 52b to the downward direction (can reduce upward bending of the extension 52b).

More specifically, the bending direction restrictor 24 has a protrusion 24a protruding laterally from the side edge of the body 21. The outwardly-standing wall 24b stands vertically upward of an end portion of the protrusion 24a in the protruding direction thereof. The protruding piece 24c is a flat plate-shaped portion disposed horizontally. The protruding piece 24c covers, from above, the extension 52b between the connection terminal 53 and the protrusion 52a.

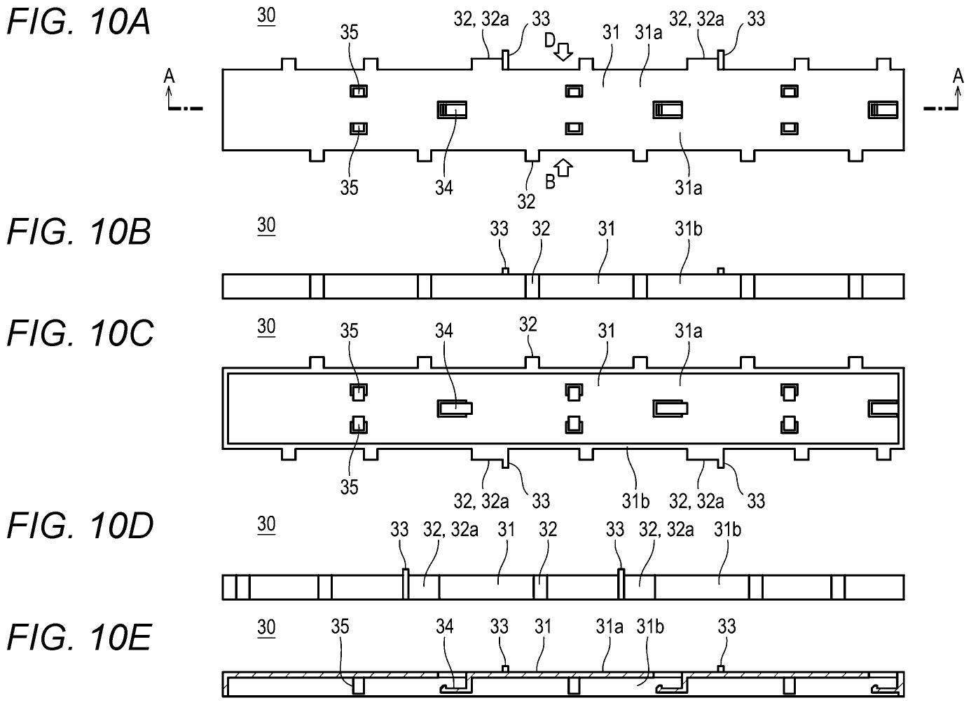

Next, the second case 30 will be described with reference to FIGS. 9A to 10E. The second case 30 includes a body 31 long in the first direction. The body 31 has, for example, the flat plate-shaped portion 31a long in the first direction and a side peripheral wall portion 31b. The side peripheral wall portion 31b hangs downward of the entire peripheral edge portion of the plate-shaped portion 31a. The plate-shaped portion 31a is disposed horizontally.

The second case 30 further includes a plurality of protrusions 32 protruding laterally from a side edge of the body 31. The protrusion 32 is a portion to which the protrusion 52a of the branch 52 is to be fixed. Thus, the protrusion 32 is disposed corresponding to the protrusion 52a of each branch 52 of the flexible printed circuit board 50. That is, the protrusions 32 include a plurality of protrusions 32 formed at one side edge of the body 31 and a plurality of protrusions 32 formed at the other side edge of the body 31. The upper surface of the protrusion 32 is formed flush with the upper surface of the plate-shaped portion 31a.

The second case 30 further includes a pressing portion 33. The pressing portion 33 receives an operation of moving the second case 30 in the first direction relative to the first case 20. The pressing portion 33 is a plate-shaped portion protruding laterally from the side edge of the body 31, for example. The plate surface of the pressing portion 33 faces the first direction (particularly, direction opposite to the movement direction of the second case 30 from the initial set position to the final set position). The number of pressing portions 33 provided for the second case 30 is not particularly limited. In the case of the present embodiment, the second case 30 includes, for example, two pressing portions 33 disposed apart from each other in the first direction. Note that the protrusion 32 is disposed at a position (particularly, adjacent position in the movement direction of the second case 30 from the initial set position to the final set position) adjacent to each pressing portion 33 in the first direction. Thus, a load when the pressing portion 33 is pressed can be received by the protrusion 32. This reduces damage to the pressing portion 33 or the like due to the load of pressing the pressing portion 33. The protrusion 32 (assigned with a reference numeral 32a in FIGS. 9A to 10E for distinguishing this protrusion 32 from the other protrusions 32) disposed adjacent to the pressing portion 33 has a greater dimension in the first direction than those of the other protrusions 32. Thus, the protrusion 32a can more suitably receive the load when the pressing portion 33 is pressed.

The second case 30 further includes the engagement portion 34 and the guide portion 35 formed on the lower surface of the plate-shaped portion 31a.

The engagement portion 34 has a hook structure having an L-shaped side surface. The engagement portion 34 is disposed so as to protrude downward from the plate-shaped portion 31a at a center portion of the plate-shaped portion 31a in the width direction thereof. The engagement portion 34 and the engagement portion 22 of the first case 20 together form the movement restrictor. Thus, the engagement portion 34 is disposed at a position corresponding to the engagement portion 22. The number of engagement portions 34 provided for the second case 30 is not particularly limited. For example, in the case of the present embodiment, the second case 30 includes three engagement portions 34 disposed apart from each other in the first direction. Note that the number of engagement portions 22 is two as described above, and therefore, there is one engagement portion 34 left out of three engagement portions 34.

The guide portion 35 is disposed so as to protrude downward from the plate-shaped portion 31a at a center portion of the plate-shaped portion 31a in the width direction thereof. The guide portion 35 is a portion having an inverted L-shaped cross section as viewed from the front. The guide portion 35 includes a pair of right and left guide portions 35 disposed on the plate-shaped portion 31a. The pair of guide portions 35 is formed bilaterally symmetrically. The guide portion 35 and the guide portion 23 of the first case 20 together form the linear guide structure. Thus, the guide portion 35 is disposed at a position corresponding to the guide portion 23. The number of guide portions 35 provided for the second case 30 is not particularly limited. For example, in the present embodiment, the second case 30 includes three pairs of guide portions 35 disposed apart from each other in the first direction. Note that the guide portion 35 and the engagement portion 34 are disposed at different positions in the first direction.

A process of assembling the first case 20 and the second case 30 may be performed as follows, for example. In the first direction, a direction of the second case 30 moving from the initial set position to the final set position relative to the first case 20 will be referred to as a “forward direction/side”, and a direction opposite to the “forward direction” will be referred to as a “backward direction/side”.

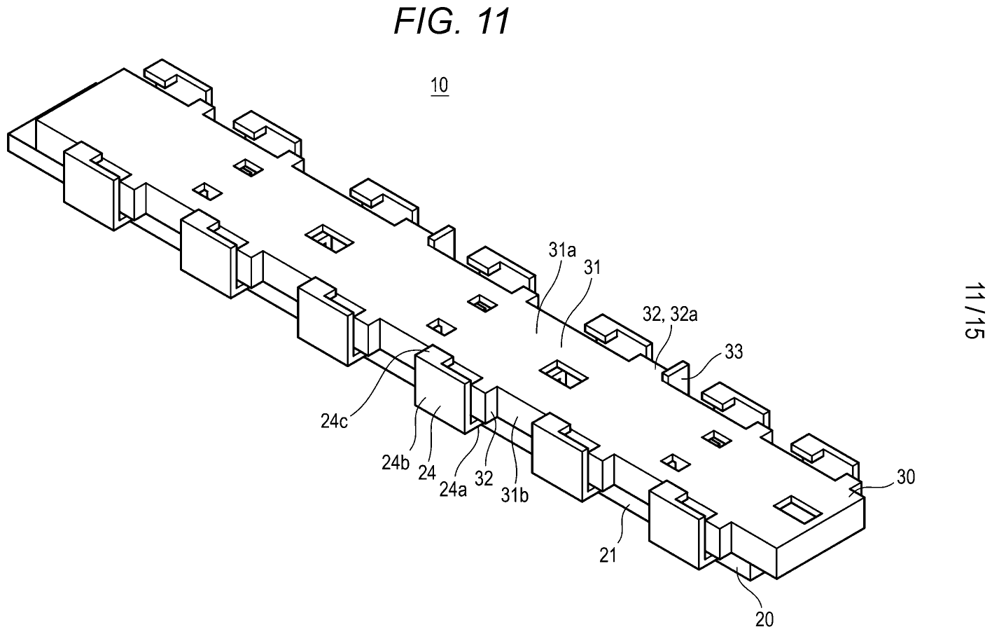

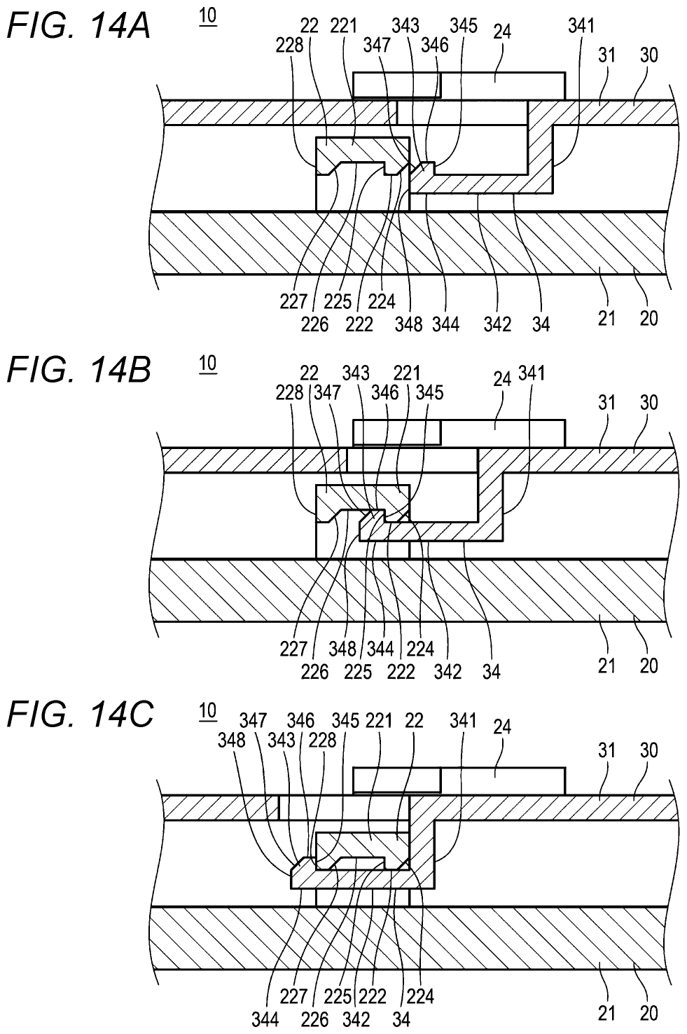

First, the second case 30 disposed above the first case 20 is lowered toward the first case 20. Then, each engagement portion 34 is disposed at a position in the vicinity of a corresponding one of the engagement portions 22 on the backward side. A state at this time is a state shown in FIGS. 11 and 14A. Note that at this time, each pair of guide portions 35 is located at a position in the vicinity of a corresponding one of the pairs of guide portions 23 on the backward side.

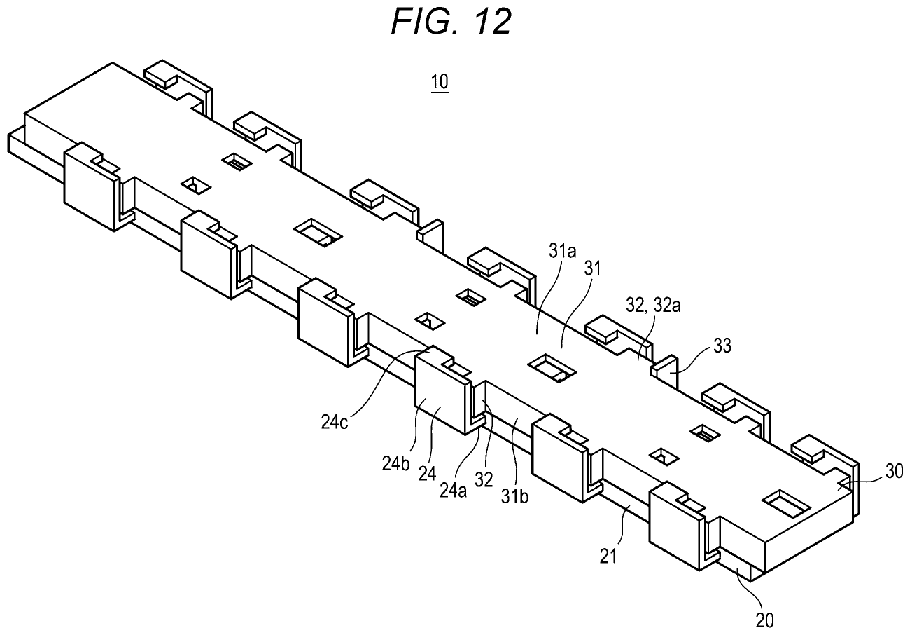

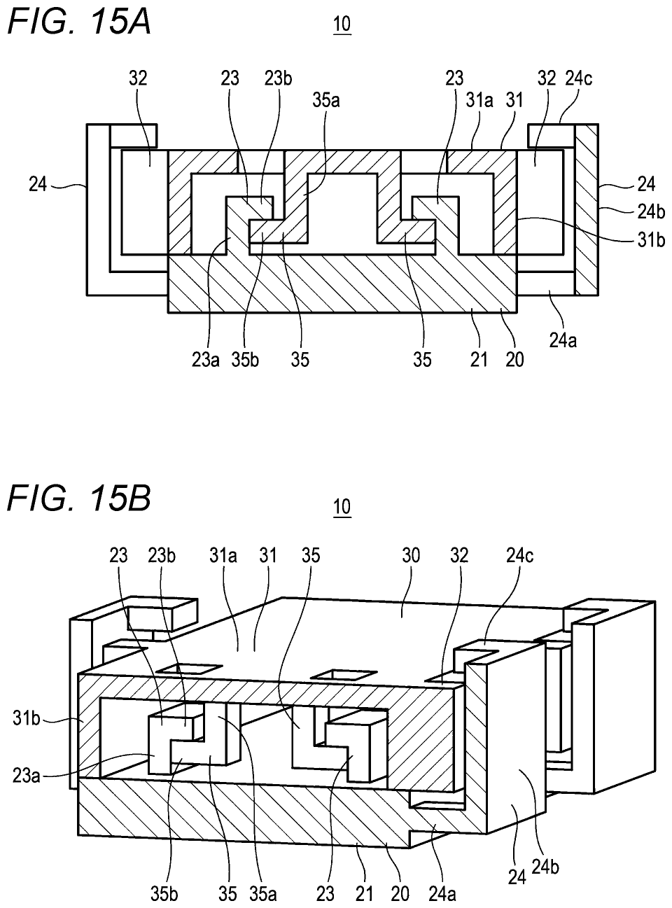

Next, the second case 30 is moved in the first direction (leftward in FIG. 14A, i.e., forward direction) relative to the first case 20, and is disposed at the initial set position. A state at this time is a state shown in FIGS. 12 and 14B. At this time, each engagement portion 34 is inserted into a corresponding one of the engagement portions 22, and the engagement portion 22 and the engagement portion 34 engage with each other. Moreover, at this time, each pair of guide portions 35 engages with a corresponding one of the pairs of guide portions 23 (see FIGS. 15A and 15B).

In this manner, a state of the first case 20 and the second case 30 being assembled can be brought. Note that the timing of fixing the flexible printed circuit board 50 to the second case 30, i.e., the timing of fixing the body 51 of the flexible printed circuit board 50 to the upper surface of the plate-shaped portion 31a and fixing the protrusion 52a to the upper surface of the protrusion 32, is not particularly limited. For example, this timing may be timing when the second case 30 is disposed at the initial set position as shown in FIGS. 12 and 14B, timing before the second case 30 is disposed at the initial set position, or timing before the second case 30 is disposed above the first case 20 as shown in FIGS. 11 and 14A.

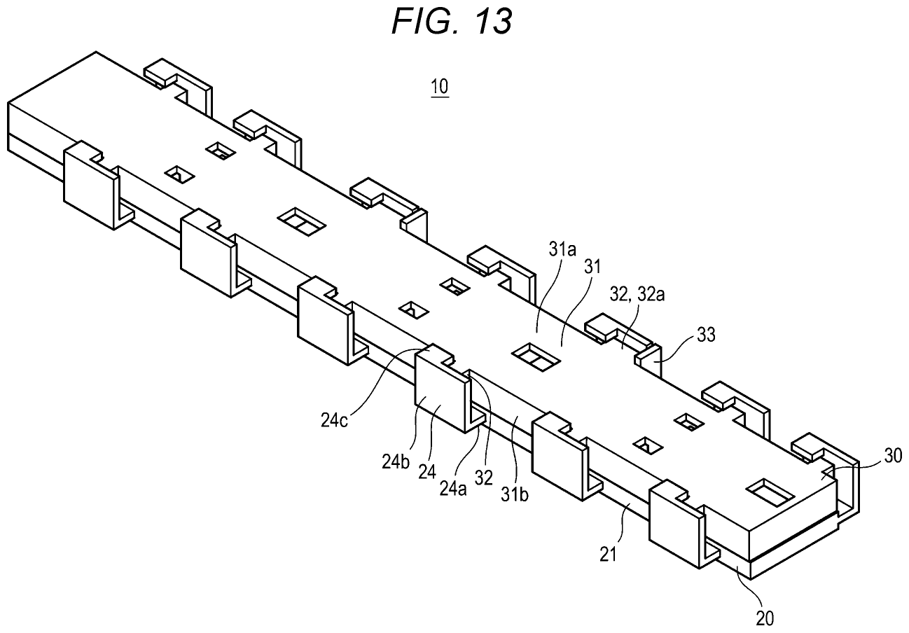

After the second case 30 has been disposed at the initial set position, each connection terminal 53 of the flexible printed circuit board 50 fixed to the second case 30 is connected in this state to a corresponding one of the busbars 70. Thereafter, by further moving the second case 30 in the first direction (leftward in FIG. 14B, i.e., forward direction) relative to the first case 20, the second case 30 is disposed at the final set position. A state at this time is a state shown in FIGS. 13 and 14C. At this time, each engagement portion 34 is inserted deeper in a corresponding one of the engagement portions 22, and the engagement portion 22 and the engagement portion 34 engage with each other. Moreover, at this time, each pair of guide portions 35 engages with a corresponding one of the pairs of guide portions 23.

The structure of the movement restrictor (including the engagement portion 22 and the engagement portion 34) will be described in more detail with reference to FIGS. 14A to 14C.

As described above, the engagement portion 22 has the gate-shaped (inverted U-shaped) cross section as viewed from the front. That is, the engagement portion 22 has a through-hole penetrating the engagement portion 22 back and forth. The engagement portion 22 has a ceiling portion 221 disposed at a position apart upward from the upper surface of the body 21. An end portion of the lower surface 222 of the ceiling portion 221 on the backward side is a first inclined surface 224 inclined downward in the forward direction. At a position apart from the first inclined surface 224 in the forward direction on the lower surface 222, a recess 226 recessed upward is formed. The inner surface of an end portion of the recess 226 on the backward side is a first standing surface 225 standing vertically. The inner surface of an end portion of the recess 226 on the forward side is a second inclined surface 227 inclined downward in the forward direction. The end surface of the ceiling portion 221 on the forward side is a second standing surface 228 standing vertically.

Meanwhile, the engagement portion 34 has a hanging portion 341 and a horizontally-extending portion 342. The hanging portion 341 hangs downward from the lower surface of the plate-shaped portion 31a of the body 31. The horizontally-extending portion 342 extends in the forward direction from a lower end portion of the hanging portion 341. A hook portion 343 to be engaged with the engagement portion 22 is formed at an end portion (end portion on the forward side) of the horizontally-extending portion 342 in the extending direction thereof. The hook portion 343 is an arrowhead-shaped portion, and protrudes upward with respect to a portion of the horizontally-extending portion 342 other than the hook portion 343. The end surface of the hook portion 343 on the backward side is a first standing surface 345 standing vertically. The hook portion 343 has an upper surface 346 horizontally extending in the forward direction from the upper edge of the first standing surface 345. The hook portion 343 has an inclined surface 347 inclined downward in the forward direction from the edge of the upper surface 346 on the forward side. The end surface of the hook portion 343 on the forward side is a tip end surface 348 standing vertically. Note that the entirety of the lower surface of the horizontally-extending portion 342 including the hook portion 343 is horizontally flat.

Next, an operation of assembling the voltage monitoring module 100 will be described. First, as shown in FIG. 14A, the second case 30 is disposed above the first case 20. Thereafter, by pressing the pressing portion 33 in the forward direction, the second case 30 is moved in the forward direction relative to the first case 20. Accordingly, for example, the inclined surface 347 of the hook portion 343 of the engagement portion 34 contacts the first inclined surface 224 of the engagement portion 22. Thereafter, the inclined surface 347 and the upper surface 346 slide on the first inclined surface 224 and the lower surface 222, and the engagement portion 34 bends downward. Thereafter, the first standing surface 345 moves over the first standing surface 225 in the forward direction, and thereafter, the engagement portion 34 is elastically restored, and accordingly, the hook portion 343 upwardly bounces and enters the recess 226. In this state, the first standing surface 345 of the hook portion 343 engages with the first standing surface 225 of the recess 226 as shown in FIG. 14B. Thus, movement of the engagement portion 34 in the backward direction relative to the engagement portion 22 is restricted. The second inclined surface 227 is located on the forward side of the inclined surface 347. Thus, as long as the hook portion 343 does not move over the second inclined surface 227, transition to the state of FIG. 14C is not made. That is, in the state of FIG. 14B, the position of the second case 30 is maintained at the initial set position.

In a state of the position of the second case 30 being maintained at the initial set position, the support case 10 including the first case 20 and the second case 30 is fixed to the housing 310, and each connection terminal 53 of the flexible printed circuit board 50 fixed to the second case 30 is connected to a corresponding one of the busbars 70.

Thereafter, by pressing the pressing portion 33 in the forward direction, the second case 30 further moves in the forward direction relative to the first case 20. Accordingly, the inclined surface 347 of the hook portion 343 of the engagement portion 34 contacts the second inclined surface 227 of the engagement portion 22. Thereafter, the inclined surface 347 and the upper surface 346 slide on the second inclined surface 227 and the lower surface 222, and the engagement portion 34 bends downward. Thereafter, after the first standing surface 345 has moved over the second standing surface 228 in the forward direction, the engagement portion 34 is elastically restored, and accordingly, the hook portion 343 upwardly bounces and the first standing surface 345 of the hook portion 343 engages with the second standing surface 228 of the engagement portion 22. In this state, movement of the engagement portion 34 in the backward direction relative to the engagement portion 22 is restricted as shown in FIG. 14C. That is, in the state of FIG. 14C, the position of the second case 30 is maintained at the final set position.

Note that as described above, in a course of the second case 30 moving to the final set position, the extension 52b of each branch 52 bends in the direction perpendicular to the plane of the extension 52b (see FIG. 6). Thus, the extension 52b can easily stretch and contract in the first direction.

As described above, the movement direction of the second case 30 relative to the first case 20 is the direction (forward direction) to one side in the first direction. The movement restrictor includes a first engagement portion (second standing surface 228 in the case of the present embodiment) provided for the first case 20 and a second engagement portion (first standing surface 345 of the hook portion 343) provided for the second case 30. By engaging the first engagement portion and the second engagement portion with each other when the second case 30 is disposed at the final set position, movement of the second case 30 to the other side (backward side), which is opposite to the one side (forward side), relative to the first case 20 is restricted. Thus, a state of the extension 52b of each branch 52 bending in the direction perpendicular to the plane of the extension 52b is suitably maintained.

In the state of FIG. 14B, when the second case 30 is disposed at the initial set position which is the position of the second case 30 before the second case 30 moves to the one side (forward side) relative to the first case 20, the movement restrictor (engagement portion 22 and engagement portion 34) allows the second case 30 to move to the one side relative to the first case 20 while maintaining the position of the second case 30 relative to the first case 20 in the first direction. Thus, when the second case 30 is at the initial set position, each connection terminal 53 of the flexible printed circuit board 50 can be stably connected to a corresponding one of the busbars 70. Note that when the second case 30 is at the initial set position, the entirety of the flexible printed circuit board 50 including the body 51 and the branch 52 is in the flat state (state of the extension 52b not bending yet).

The movement restrictor includes a third engagement portion (for example, recess 226 provided for the first case 20) provided for the first case 20 or the second case 30. When the second case 30 is disposed at the initial set position, the first or second engagement portion engages with the third engagement portion (the second engagement portion and the third engagement portion engage with each other in the case of the present embodiment), and in this manner, movement of the second case 30 to the one side relative to the first case 20 is allowed while the position of the second case 30 relative to the first case 20 in the first direction is held. That is, in the movement restrictor of the present embodiment, the first or second engagement portion (second engagement portion in the case of the present embodiment) used for bringing the engagement state of the first case 20 and the second case 30 when the second case 30 is disposed at the final set position is also used for bringing the engagement state of the first case 20 and the second case 30 when the second case 30 is disposed at the initial set position. Thus, the structure of the movement restrictor can be simplified.

In the case of the present embodiment, the first case 20 has the third engagement portion (recess 226), and by engaging the second engagement portion and the third engagement portion with each other when the second case 30 is disposed at the initial set position, movement of the second case 30 to the one side relative to the first case 20 is allowed while the position of the second case 30 relative to the first case 20 in the first direction is maintained.

Note that the present embodiment is not limited to this example. The second case 30 may have the third engagement portion, and by engaging the first engagement portion and the third engagement portion with each other when the second case 30 is disposed at the initial set position, movement of the second case 30 to the one side relative to the first case 20 may be allowed while the position of the second case 30 relative to the first case 20 in the first direction is maintained. For example, the engagement portion 34 may have two hook portions apart from each other in the first direction. The hook portion on the forward side among these hook portions may be the third engagement portion, the hook portion on the backward side may be the second engagement portion, and the recess 226 of the engagement portion 22 may be the first engagement portion.

Next, the linear guide structure (including the guide portion 23 and the guide portion 35) will be described in more detail with reference to FIGS. 15A and 15B. The linear guide structure is a structure for linearly and slidably guiding the second case 30 in the first direction relative to the first case 20. The voltage monitoring module 100 includes the linear guide structure, so that the second case 30 can linearly move in the first direction. Thus, when the extension 52b bends, a defect such as twisting of the extension 52b can be reduced.

As described above, the pair of right and left guide portions 23 is disposed on the body 21. One of the pair of guide portions 23 has a standing portion 23a and a horizontally-protruding portion 23b. The standing portion 23a stands upward of the upper surface of the body 21. The horizontally-protruding portion 23b protrudes to the other guide portion 23 (inward in the width direction of the support case 10) from an upper end portion of the standing portion 23a. Similarly, the other one of the pair of guide portions 23 has a standing portion 23a and a horizontally-protruding portion 23b. The standing portion 23a stands upward of the upper surface of the body 21. The horizontally-protruding portion 23b protrudes to the one guide portion 23 (inward in the width direction of the support case 10) from an upper end portion of the standing portion 23a.

The pair of right and left guide portions 35 is disposed on the plate-shaped portion 31a of the body 31. One of the pair of guide portions 35 has a hanging portion 35a and a horizontally-protruding portion 35b. The hanging portion 35a hangs downward of the lower surface of the plate-shaped portion 31a of the body 31. The horizontally-protruding portion 35b protrudes to the side opposite to the other guide portion 35 (outward in the width direction of the support case 10) from a lower end portion of the hanging portion 35a. Similarly, the other one of the pair of guide portions 35 has a hanging portion 35a and a horizontally-protruding portion 35b. The hanging portion 35a hangs downward of the lower surface of the plate-shaped portion 31a of the body 31. The horizontally-protruding portion 35b protrudes to the side opposite to the one guide portion 35 (outward in the width direction of the support case 10) from a lower end portion of the hanging portion 35a.

The one guide portion 23 and the one guide portion 35 engage with each other, and the other guide portion 23 and the other guide portion 35 engage with each other. More specifically, the tip end surface of the horizontally-protruding portion 35b of the one guide portion 35 is in the vicinity of or in contact with the inner surface (surface facing the center side in the width direction of the support case 10) of the standing portion 23a of the one guide portion 23. Moreover, the upper surface of the horizontally-protruding portion 35b of the one guide portion 35 is in the vicinity of or in contact with the lower surface of the horizontally-protruding portion 23b of the one guide portion 23. The horizontally-protruding portion 35b of the one guide portion 35 is vertically sandwiched by the horizontally-protruding portion 23b of the one guide portion 23 and the body 21. Similarly, the tip end surface of the horizontally-protruding portion 35b of the other guide portion 35 is in the vicinity of or in contact with the inner surface (surface facing the center side in the width direction of the support case 10) of the standing portion 23a of the other guide portion 23. Moreover, the upper surface of the horizontally-protruding portion 35b of the other guide portion 35 is in the vicinity of or in contact with the lower surface of the horizontally-protruding portion 23b of the other guide portion 23. The horizontally-protruding portion 35b of the other guide portion 35 is vertically sandwiched by the horizontally-protruding portion 23b of the other guide portion 23 and the body 21. Thus, by the linear guide structure including the pair of guide portions 23 and the pair of guide portions 35, the second case 30 is linearly and slidably guided in the first direction relative to the first case 20. In the case of the present embodiment, the linear guide structure includes plural pairs (for example, three pairs) of guide portions 23 and plural pairs (for example, three pairs) of guide portions 35. Thus, the linear guide structure can linearly and slidably guide the second case 30 with higher accuracy.

As described above, the linear guide structure includes a first guide portion (for example, including the guide portion 23 and the body 21) provided for one of the first case 20 or the second case 30, and a second guide portion (for example, guide portion 35) provided for the other one of the first case 20 or the second case 30. The first guide portion sandwiches the second guide portion from both sides in a direction (i.e., up-down direction) perpendicular to the planar direction of the body 51, thereby linearly and slidably guiding the second guide portion in the first direction. In the case of the present embodiment, the standing portion 23a and the tip end surface of the horizontally-protruding portion 35b are in the vicinity of or in contact with each other. Thus, relative displacement of the first case 20 and the second case 30 in the width direction can also be reduced.

Note that in the flexible printed circuit board 50, no only the body 51 thereof is fixed to the upper surface of the plate-shaped portion 31a, but also the protrusion 52a is fixed to the upper surface of the protrusion 32. Thus, in a course of the second case 30 moving to the final set position, only the extension 52b can bend (deflects).

Each embodiment has been described above with reference to the drawings. These embodiments are examples of the aspects of the present disclosure, and various configurations other than those described above may be employed.

The present embodiment includes the following technical ideas.
(1) A voltage monitoring module for monitoring a state of a voltage of a cell laminate including a plurality of battery cells laminated on each other, the voltage monitoring module including: a flexible printed circuit board having a plurality of lines; and a support case supporting the flexible printed circuit board, in which the flexible printed circuit board includes a body and a branch branched from the body and having an extension extending in a first direction which is a longitudinal direction of the body, the branch has, at a tip end portion thereof, a connection terminal to be connected to a cell terminal which is a terminal of each battery cell, the support case includes a first case, a second case having a body mounting portion on which the body is to be mounted and provided movably in the first direction relative to the first case, and a movement restrictor that restricts movement of the second case, which is disposed at a final set position which is a position of the second case after the second case has moved in the first direction relative to the first case, relative to the first case.
(2) The voltage monitoring module according to (1), in which a movement direction of the second case relative to the first case is a direction to one side in the first direction, the movement restrictor includes a first engagement portion provided for the first case and a second engagement portion provided for the second case, and by engaging the first engagement portion and the second engagement portion with each other when the second case is disposed at the final set position, movement of the second case to the other side, which is opposite to the one side, relative to the first case is restricted.
(3) The voltage monitoring module according to (2), in which when the second case is disposed at an initial set position which is a position of the second case before the second case moves to the one side relative to the first case, the movement restrictor allows the second case to move to the one side relative to the first case while maintaining a position of the second case relative to the first case in the first direction.
(4) The voltage monitoring module according to (3), in which the movement restrictor includes a third engagement portion provided for the first case or the second case, and when the second case is disposed at the initial set position, by engaging the first or second engagement portion with the third engagement portion, movement of the second case to the one side relative to the first case is allowed while the position of the second case relative to the first case in the first direction is maintained.
(5) The voltage monitoring module according to (4), in which the first case has the third engagement portion, and by engaging the second engagement portion and the third engagement portion with each other when the second case is disposed at the initial set position, movement of the second case to the one side relative to the first case is allowed while the position of the second case relative to the first case in the first direction is maintained.
(6) The voltage monitoring module according to any one of (1) to (5), further including: a linear guide structure capable of linearly and slidably guiding the second case in the first direction relative to the first case.
(7) The voltage monitoring module according to (6), in which the linear guide structure includes a first guide portion provided for one of the first case or the second case, and a second guide portion provided for the other one of the first case or the second case, and the first guide portion sandwiches the second guide portion from both sides in a direction perpendicular to a planar direction of the body, thereby linearly and slidably guiding the second guide portion in the first direction.
(8) A battery module including: the voltage monitoring module according to any one of (1) to (7); and the cell laminate, in which after the second case has been disposed at an initial set position which is a position of the second case before the second case moves in the first direction relative to the first case, the body has been mounted on the body mounting portion, and the connection terminal of the flexible printed circuit board has been connected to the cell terminal of the cell laminate, the second case moves to the final set position in the first direction relative to the first case, and the extension bends in a direction perpendicular to a plane of the extension.
(9) The battery module according to (8), in which the first case has a bending direction restrictor that restricts a bending direction of the extension to one direction in a direction perpendicular to a plane of the body in a course of the second case moving to the final set position in the first direction relative to the first case.
(10) The battery module according to (9), in which the bending direction restrictor has an outwardly-standing wall standing in the direction perpendicular to the plane of the body on an outside of an outer line of the flexible printed circuit board as viewed in the direction perpendicular to the plane of the body, and a protruding piece protruding inward of the outer line from the outwardly-standing wall and covering the extension.
(11) A support case including: a first case; a second case having a body mounting portion on which a body of a flexible printed circuit board is to be mounted and movably provided in a first direction, which is a longitudinal direction of the body, relative to the first case; and a movement restrictor that restricts movement of the second case, which is disposed at a final set position which is a position of the second case after the second case has moved in the first direction relative to the first case, relative to the first case.

The foregoing detailed description has been presented for the purposes of illustration and description. Many modifications and variations are possible in light of the above teaching. It is not intended to be exhaustive or to limit the subject matter described herein to the precise form disclosed. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims appended hereto.

What is claimed is:

1. A voltage monitoring module for monitoring a state of a voltage of a cell laminate including a plurality of battery cells laminated on each other, comprising:
a flexible printed circuit board having a plurality of lines; and
a support case supporting the flexible printed circuit board,
wherein the flexible printed circuit board includes a body and a branch branched from the body and having an extension extending in a first direction which is a longitudinal direction of the body,
the branch has, at a tip end portion thereof, a connection terminal to be connected to a cell terminal which is a terminal of each battery cell,
the support case includes
a first case,
a second case having a body mounting portion on which the body is to be mounted and provided movably in the first direction relative to the first case, and
a movement restrictor that restricts movement of the second case, which is disposed at a final set position which is a position of the second case after the second case has moved in the first direction relative to the first case, relative to the first case.

2. The voltage monitoring module according to claim 1, wherein
a movement direction of the second case relative to the first case is a direction to one side in the first direction,
the movement restrictor includes a first engagement portion provided for the first case and a second engagement portion provided for the second case, and
by engaging the first engagement portion and the second engagement portion with each other when the second case is disposed at the final set position, movement of the second case to the other side, which is opposite to the one side, relative to the first case is restricted.

3. The voltage monitoring module according to claim 2, wherein
when the second case is disposed at an initial set position which is a position of the second case before the second case moves to the one side relative to the first case, the movement restrictor allows the second case to move to the one side relative to the first case while maintaining a position of the second case relative to the first case in the first direction.

4. The voltage monitoring module according to claim 3, wherein
the movement restrictor includes a third engagement portion provided for the first case or the second case, and
when the second case is disposed at the initial set position, by engaging the first or second engagement portion with the third engagement portion, movement of the second case to the one side relative to the first case is allowed while the position of the second case relative to the first case in the first direction is maintained.

5. The voltage monitoring module according to claim 4, wherein
the first case has the third engagement portion, and
by engaging the second engagement portion and the third engagement portion with each other when the second case is disposed at the initial set position, movement of the second case to the one side relative to the first case is allowed while the position of the second case relative to the first case in the first direction is maintained.

6. The voltage monitoring module according to claim 1, further comprising:
a linear guide structure capable of linearly and slidably guiding the second case in the first direction relative to the first case.

7. The voltage monitoring module according to claim 6, wherein
the linear guide structure includes a first guide portion provided for one of the first case or the second case, and a second guide portion provided for the other one of the first case or the second case, and
the first guide portion sandwiches the second guide portion from both sides in a direction perpendicular to a planar direction of the body, thereby linearly and slidably guiding the second guide portion in the first direction.

8. A battery module comprising:
the voltage monitoring module according to claim 1; and
the cell laminate,
wherein after the second case has been disposed at an initial set position which is a position of the second case before the second case moves in the first direction relative to the first case, the body has been mounted on the body mounting portion, and the connection terminal of the flexible printed circuit board has been connected to the cell terminal of the cell laminate, the second case moves to the final set position in the first direction relative to the first case, and the extension bends in a direction perpendicular to a plane of the extension.

9. The battery module according to claim 8, wherein
the first case has a bending direction restrictor that restricts a bending direction of the extension to one direction in a direction perpendicular to a plane of the body in a course of the second case moving to the final set position in the first direction relative to the first case.

10. The battery module according to claim 9, wherein
the bending direction restrictor has an outwardly-standing wall standing in the direction perpendicular to the plane of the body on an outside of an outer line of the flexible printed circuit board as viewed in the direction perpendicular to the plane of the body, and a protruding piece protruding inward of the outer line from the outwardly-standing wall and covering the extension.

11. A support case comprising:
a first case;
a second case having a body mounting portion on which a body of a flexible printed circuit board is to be mounted and movably provided in a first direction, which is a longitudinal direction of the body, relative to the first case; and
a movement restrictor that restricts movement of the second case, which is disposed at a final set position which is a position of the second case after the second case has moved in the first direction relative to the first case, relative to the first case.
